(19) United States
(12) Patent Application Publication
(10) Pub. No.: US 2008/0069003 A1
(43) Pub. Date: Mar. 20, 2008

(54) Testing Apparatus And Testing Method

(75) Inventors: Kenichiro Shinoi, Kanagawa (JP); Hidetoshi Suzuki, Kanagawa (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., OSAKA (JP)

(21) Appl. No.: 11/628,795

(22) PCT Filed: Jun. 3, 2005
(86) PCT No.: PCT/JP05/10274

§ 371 Date: Dec. 7, 2006

(30) Foreign Application Priority Data
Jun. 10, 2004 (JP) 2004-172411

(51) Int. Cl. G01R 31/08; G06F 11/00

(52) U.S. Cl. 370/248

(57) ABSTRACT

A testing apparatus capable of testing the reception performance of a communication terminal apparatus to be tested, while determining whether a selecting/combining function is implemented in the communication terminal apparatus. In the testing apparatus, a transmission control part (103) designates, to a selecting part (104), a timing at which to switch spread codes to be outputted. The selecting part (104) selects, in accordance with the designation of the transmission control part (103), either a first spread code generated by a first code generating part (101) or a second spread code generated by a second code generating part (102). A spreading part (106) multiplies a packet outputted from an outbound packet generating part (105) by a spread code outputted from the selecting part (104) for output. A measuring part (151) receives a report as to whether the packet from a communication terminal apparatus (200) has been correctly decoded, calculates a packet error rate, and outputs the calculation result.

### TECHNICAL FIELD

The present invention relates to a testing apparatus and testing method for testing reception performance of a communication terminal apparatus used in a wireless communication system.

### BACKGROUND ART

In Release 6 of 3GPP (3rd Generation Partnership Project), a selective combining function (selective combining) that receives and decodes the same information for each cell sent from base station apparatuses of a plurality of different cells and only selects information that has been correctly decoded at a communication terminal apparatus, is specified as an essential function.

The selective combining function studied in the 3GPP MBMS (Multimedia Broadcast Multicast Service) specification is a scheme for improving reception performance by sending packets having the same information from base station apparatuses of two cells, and after carrying out reception/decoding independently, selecting packets that have been correctly decoded at the communication terminal apparatus.

In the case of using the selective combining function, even when packets received from one base station apparatus have not been correctly decoded, packets received from the other base station apparatus may be correctly decoded, so that it is possible to reduce the total error rate, improve system throughput and improve capacity by reducing transmission power of the base station apparatus. In Release 6, it can be considered that a specification with strict requirements is established compared to the case of not carrying out the selective combining function. As an example showing a specific effect, Non-Patent Document 1 discloses link level simulation results for the case of carrying out the selective combining function.

As a method for improving reception performance of the communication terminal apparatus, a method of arranging a plurality of receiving antennas and combining multipaths (reception diversity) is known. In the case of using this method, reception performance is improved compared to the case of reception using a single antenna, and therefore, even if a selective combining function is not carried out, the desired requirement specification (throughput) may be achieved by only receiving packets from a single base station apparatus.

Therefore, in the case of carrying out reception performance testing of the communication terminal apparatus hereafter, it is considered to be necessary to identify whether improvement in throughput is due to the selective combining function or due to reception diversity.
Non-patent document 1: R1-031103 (TSG-RAN Working Group 1 #32)

### DISCLOSURE OF INVENTION

Problems to be Solved by the Invention

However, up until now, there is no testing apparatus/testing method having a function for determining whether or not a selective combining function is implemented at the communication terminal apparatus subject to testing.

It is therefore an object of the present invention to provide a testing apparatus and testing method capable of testing reception performance of a communication terminal apparatus subject to testing and capable of determining whether or not a selective combining function is implemented at the communication terminal apparatus.

Means for Solving the Problem

In order to solve this problem, a testing apparatus of the present invention that sends packets after spreading to the communication terminal apparatus and tests reception performance of the communication terminal apparatus using error rate of received packets of the communication terminal apparatus, adopts a configuration having: a spreading code generating section that generates a plurality of types of spreading codes; a transmission packet generating section that generates packets; a transmission control section that controls a timing of switching of the spreading codes; a selection section that selects one of the spreading codes generated by the spreading code generating section based on control of the transmission control section; and a spreading section that multiplies packets generated at the transmission packet generating section by the spreading code selected by the selection section.

Further, the testing apparatus of the present invention that sends packets after spreading to the communication terminal apparatus and tests reception performance of the communication terminal apparatus using error rate of received packets of the communication terminal apparatus adopts a configuration having: a spreading code generating section that generates a plurality of types of spreading codes; a transmission packet generating section that generates packets configuring a plurality of packet series; and a spreading section that multiplies packets generated at the transmission packet generating section by the spreading code so that the spreading code is different for each packet series.

Still further, a testing method of the present invention that sends packets after spreading to the communication terminal apparatus and tests reception performance of the communication terminal apparatus using error rate of received packets of the communication terminal apparatus adopts a configuration having: a spreading code generating step of generating a plurality of types of spreading codes; a transmission packet generating step of generating packets; a transmission control step of controlling a timing of switching of the spreading codes; a selection step of selecting one of the spreading codes generated by the spreading code generating step based on control of the transmission control step; and a spreading step of multiplying packets generated at the transmission packet generating step by the spreading code selected by the selection step.

Moreover, the testing method of the present invention that sends packets after spreading to the communication terminal apparatus and tests reception performance of the communication terminal apparatus using error rate of received packets of the communication terminal apparatus adopts a configuration having: a spreading code generating step of generating a plurality of types of spreading codes; a transmission packet generating step of generating packets configuring a plurality of packet series; and a spreading step of multiplying packets generated in the transmission packet generating step by the spreading code so that the spreading code is different for each packet series.

Advantageous Effect of the Invention

According to the present invention, it is possible to test reception performance of the communication terminal apparatus and determine whether or not a selective combining function is implemented at the communication terminal apparatus subject to testing.

### BRIEF DESCRIPTION OF THE DRAWINGS

FIG. 1 is a block diagram showing a configuration of a testing apparatus according to Embodiment 1 of the present invention;

FIG. 2 shows an example of a packet series sent from the testing apparatus according to Embodiment 1 of the present invention;

FIG. 3 is a block diagram showing a configuration of the testing apparatus according to Embodiment 2 of the present invention;

FIG. 4 shows an example of a packet series sent from the testing apparatus according to Embodiment 2 of the present invention;

FIG. 5 further shows an example of the packet series sent from the testing apparatus according to Embodiment 2 of the present invention;

FIG. 6 further shows an example of the packet series sent from the testing apparatus according to Embodiment 2 of the present invention; and

FIG. 7 still further shows an example of the packet series sent from the testing apparatus according to Embodiment 2 of the present invention.

### BEST MODE FOR CARRYING OUT THE INVENTION

Embodiments of the present invention will be described below in detail with reference to the accompanying drawings. In each of the embodiments below, a case will be described of testing reception performance of the communication terminal apparatus in a situation where packets multiplied by mutually different spreading codes are sent from two base station apparatuses.

### Embodiment 1

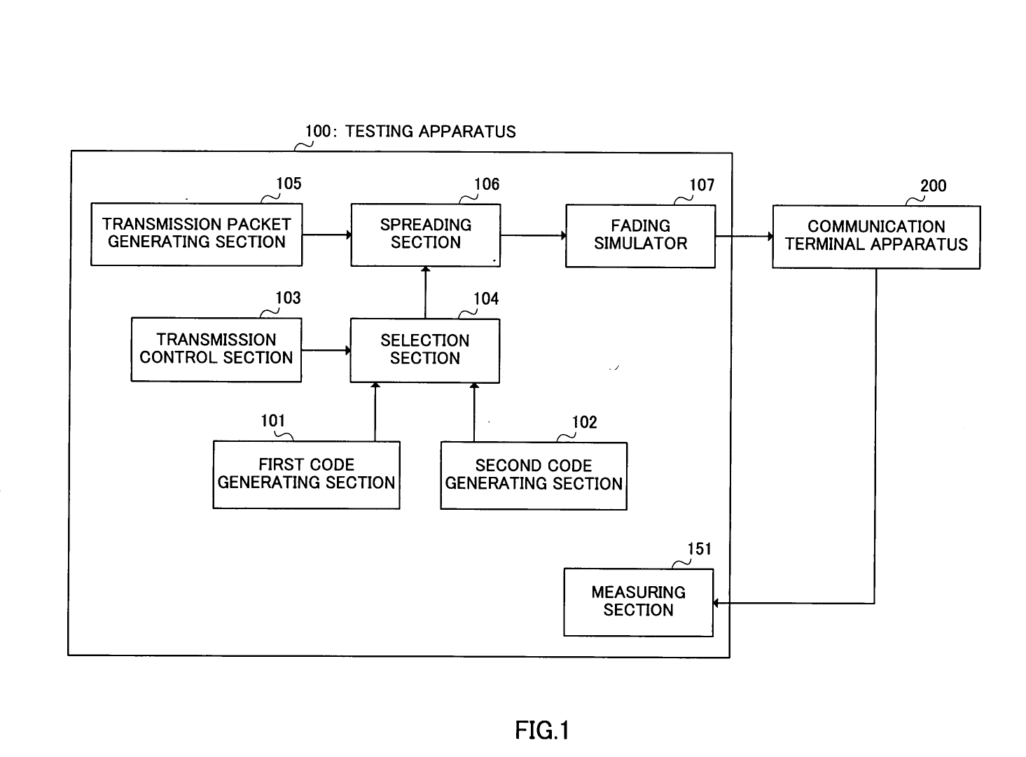

FIG. 1 is a block diagram showing a configuration of a testing apparatus of Embodiment 1 of the present invention. Testing apparatus 100 is an apparatus that outputs spread packets to communication terminal apparatus 200 that is subject to testing, receives information as to whether or not packets have been correctly decoded at communication terminal apparatus 200, and tests reception performance of communication terminal apparatus 200 by calculating packet error rate.

Each configuration of testing apparatus 100 will be described below. Testing apparatus 100 is mainly configured with first code generating section 101, second code generating section 102, transmission control section 103, selection section 104, transmission packet generating section 105, spreading section 106, fading simulator 107 and measuring section 151.

First code generating section 101 generates a first spreading code (hereinafter referred to as “first code”), and outputs this code to selection section 104. Second code generating section 102 generates a second spreading code (hereinafter referred to as “second code”) and outputs this code to selection section 104. The first code and second code are provided in advance before the test starts.

Transmission control section 103 instructs selection section 104 on a timing of switching spreading codes to be outputted. Selection section 104 selects either the first code or the second code according to the instruction from transmission control section 103 and outputs the selected spreading code to spreading section 106.

Transmission packet generating section 105 generates transmission packets used in testing and outputs the result to spreading section 106. Spreading section 106 spreads packets by multiplying the packets outputted from transmission packet generating section 105 by the spreading code outputted from selection section 104 and outputs the spread packets to fading simulator 107. Fading simulator 107 creates a simulated time-space characteristic for an actual communication environment, adds multipaths to the packets outputted from spreading section 106 and outputs the result to communication terminal apparatus 200.

Measuring section 151 receives a report as to whether or not packets from communication terminal apparatus 200 have been correctly decoded, calculates packet error rate, and outputs a calculation result. As an outputting method at measuring section 151, displaying at a display screen, outputting by printing on a chart, or the like may be given.

Next, the testing method according to this embodiment will be described using a specific example. The first code and second code are provided in advance to testing apparatus 100 and communication terminal apparatus 200 before the test starts. Further, synchronization is established between testing apparatus 100 and communication terminal apparatus 200 before the test starts.

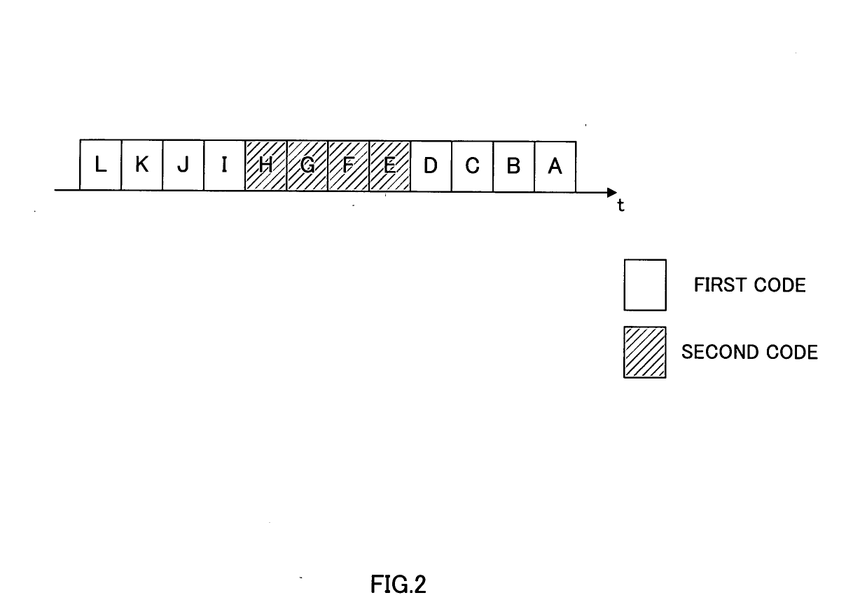

First, a series of packets spread using the first code or the second code is sent from testing apparatus 100. The spreading code multiplied with the packets can be switched at a predetermined timing, and in this example, as shown in FIG. 2, it is assumed that packets A to D and I to L are multiplied by the first code, and packets E to H are multiplied by the second code.

Communication terminal apparatus 200 determines for each packet whether or not the packet has been correctly decoded, and reports the determination result to testing apparatus 100. Here, in the case where a selective combining function is implemented, communication terminal apparatus 200 carries out despreading processing using the first code and the second code. When a packet has been correctly decoded in at least one spreading code, communication terminal apparatus 200 determines for each packet that the packet has been correctly decoded, and, when the packet has not been correctly decoded though using both spreading codes, determines that the packet has not been correctly decoded. On the other hand, in the case where a selective combining function is not implemented, communication terminal apparatus 200 carries out despreading processing using one of the first code and the second code, and determines for each packet whether or not the packet has been correctly decoded.

Testing apparatus 100 calculates packet error rate based on the report received from communication terminal apparatus 200 and outputs the calculation result.

As a result, in this example, in the case where communication terminal apparatus 200 implements a selective combining function, and reception performance is good, and when error rate is measured over all the packets (A to L), the error rate becomes lower than the predetermined error rate. Further, in the case where communication terminal apparatus 200 does not implement a selective combining function, and reception quality is good, it is only possible to receive one of the packets (A to D, I to L) multiplied by the first code and the packets (E to H) multiplied by the second code. Therefore, in the case of measuring error rate over all the packets (A to L), the error rate becomes higher than the predetermined value, and it is not possible to pass the test. Further, in the case where reception performance of communication terminal apparatus 200 is poor, the error rate becomes higher than a predetermined value over all the packets (A to L), so that it is not possible to pass the test.

In this way, according to this embodiment, the testing apparatus switches between a plurality of mutually different spreading codes, multiplies the packets by these codes, transmits the results, and calculates and outputs error rate based on a report of a decoding result for each packet received from the communication terminal apparatus, so that it is possible to test reception performance of the communication terminal apparatus and determine whether or not a selective combining function is implemented at the communicating terminal apparatus subject to testing.

### Embodiment 2

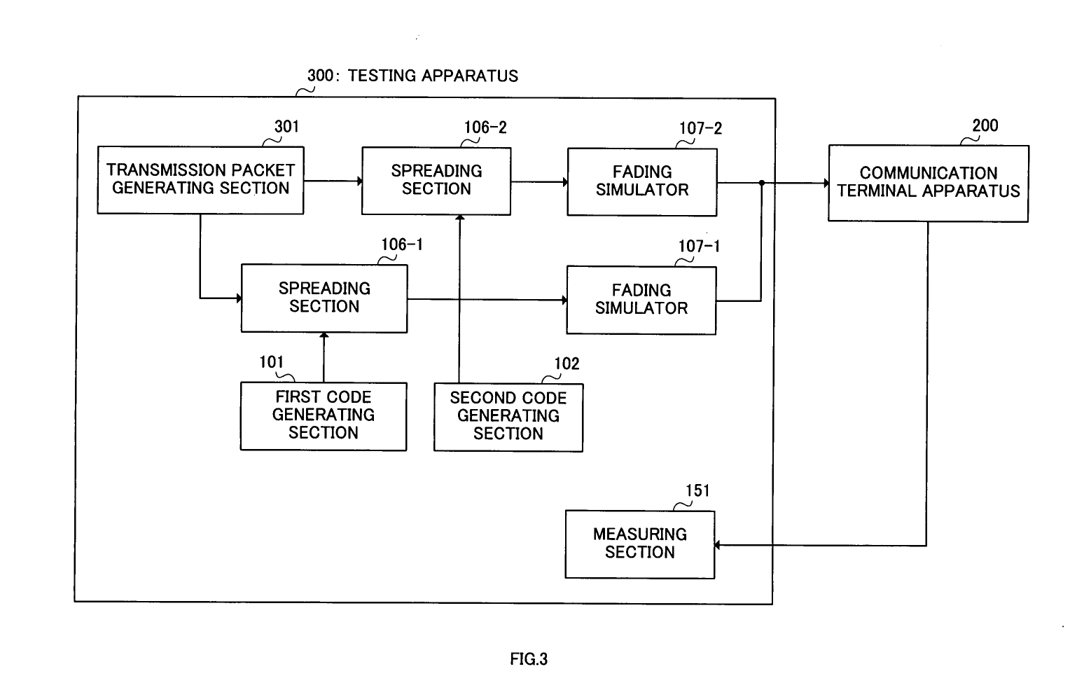

FIG. 3 is a block diagram showing a configuration of a testing apparatus according to Embodiment 2 of the present invention. At testing apparatus 300 shown in FIG. 3, components that are common with testing apparatus 100 shown in FIG. 1 are assigned the same reference numerals as in FIG. 1 without further explanations.

Testing apparatus 300 shown in FIG. 3, compared to testing apparatus 100 shown in FIG. 1, adopts a configuration where transmission control section 103, selection section 104 and transmission packet generating section 105 are removed, but transmission packet generating section 301 is added. Further, testing apparatus 300 shown in FIG. 3 has two spreading sections 106-1 and 106-2, and two fading simulators 107-1 and 107-2.

Transmission packet generating section 301 generates transmission packets used in testing and configures two packet series, with one packet series being outputted to spreading section 106-1 and the other packet series being outputted to spreading section 106-2.

Spreading section 106-1 spreads packets by multiplying packets outputted from transmission packet generating section 301 by the first code outputted from first code generating section 101 and outputs the spread packets to fading simulator 107-1. In the case where packets are not outputted from transmission packet generating section 301, a signal is not outputted from spreading section 106-1. Spreading section 106-2 spreads packets by multiplying packets outputted from transmission packet generating section 301 by the second code outputted from second code generating section 102 and outputs the spread packets to fading simulator 107-2. In the case where packets are not outputted from transmission packet generating section 301, a signal is not outputted from spreading section 106-2.

Fading simulators 107-1 and 107-2 create a simulated time-space characteristic for an actual communication environment, and add multipaths to packets outputted from spreading sections 106-1 and 106-2. Output signals of fading simulators 107-1 and 107-2 are code-multiplexed and outputted to communication terminal apparatus 200.

Next, the testing method according to this embodiment will be described using a specific example. The first code and second code are provided in advance to testing apparatus 300 and communication terminal apparatus 200 before the test starts. Further, synchronization is established between testing apparatus 300 and communication terminal apparatus 200 before the test starts.

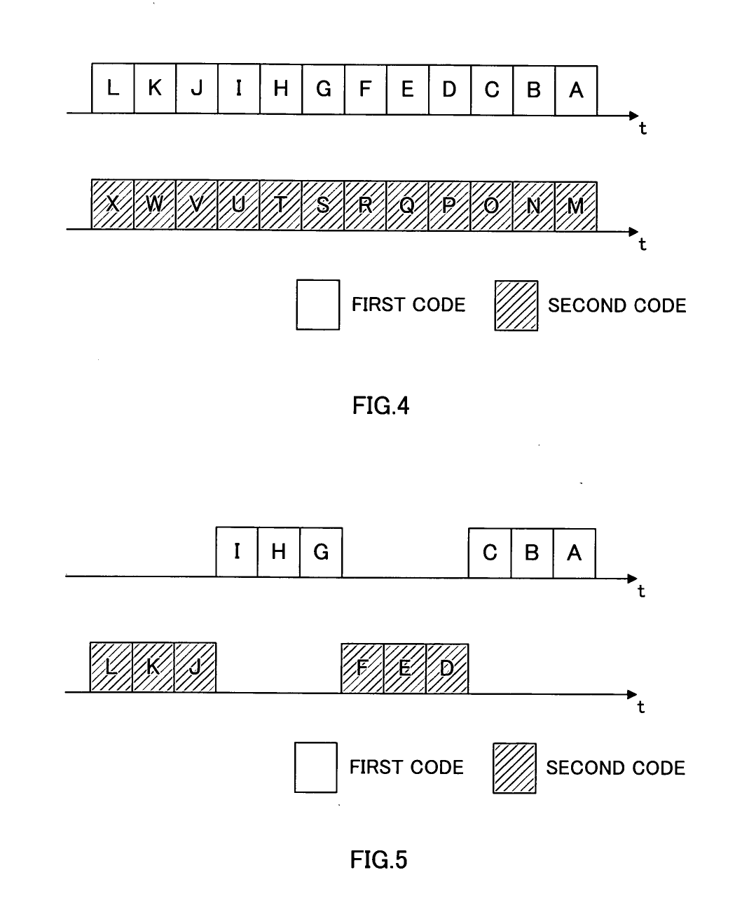

First, a series of packets spread using the first code and a series of packets spread using the second code are sent from testing apparatus 300. In this example, as shown in FIG. 4, it is assumed that a series where packets A to L are multiplied by the first code and a series where packets M to X are multiplied by the second code are respectively transmitted.

Communication terminal apparatus 200 determines for each packet whether or not the packet has been correctly decoded, and reports the determination result to testing apparatus 300. Here, in the case where a selective combining function is implemented, communication terminal apparatus 200 carries out despreading processing using the first code and the second code. When the packet has been correctly decoded in at least one spreading code, communication terminal apparatus 200 determines that the packet has been correctly decoded, and when the packet has not been correctly decoded though using the both spreading codes, determines that the packet has not been correctly decoded. On the other hand, in the case where a selective combining function is not implemented, communication terminal apparatus 200 carries out despreading processing using one of the first code and the second code, and determines for each packet whether or not the packet has been correctly decoded.

Testing apparatus 300 calculates packet error rate based on a report received from communication terminal apparatus 200 and outputs the calculation result.

As a result, in this example, in the case where communication terminal apparatus 200 implements a selective combining function, and reception performance is good, the error rate becomes lower than a predetermined value over all the packets (A to X). Further, in the case where communication terminal apparatus 200 does not implement a selective combining function, and reception quality is good, it is only possible to receive one of the packets (A to L) multiplied by the first code and the packets (M to X) multiplied by the second code, and therefore in the case of measuring error rate over all the packets (A to X), the error rate becomes higher than the predetermined value, and it is not possible to pass the test. Further, in the case where reception performance of communication terminal apparatus 200 is poor, the error rate becomes higher than a predetermined value over all the packets (A to X) and it is not possible to pass the test.

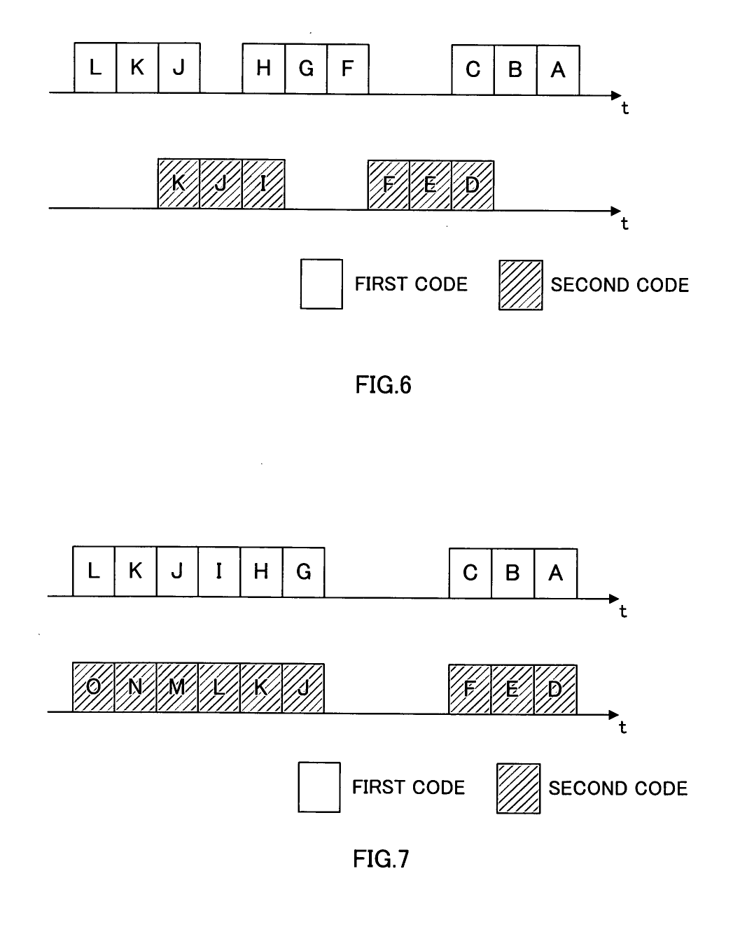

In this embodiment, a case has been described where two packet series of consecutive packets are sent from testing apparatus 300, but the present invention is by no means limited in this respect, and, for example, one packet series may be divided into two and sent as shown in FIG. 5. Further, as shown in FIG. 6 and FIG. 7, a part of packets may be sent using one packet series, with the other packets being sent using both packet series. Moreover, in the present invention, the packet series do not have to be mutually synchronized.

In this way, according to this embodiment, the testing apparatus sends a plurality of packet series multiplied by mutually different spreading codes and calculates and outputs error rate based on a report of a decoding result for each packet received from the communication terminal apparatus, so that it is possible to test reception performance of the communication terminal apparatus and determine whether or not a selective combining function is implemented at the communication terminal apparatus that is subject to testing.

In each of the above-described embodiments, a case has been described where a fading simulator is provided within the testing apparatus, but the present invention is by no means limited in this respect, and a configuration is also possible where the fading simulator is provided as a separate apparatus from the testing apparatus. Further, in each of the above-described embodiments, a case has been described where a measuring section is provided within the testing apparatus, but the present invention is by no means limited in this respect, and a configuration is also possible where the measuring section is provided as a separate apparatus from the testing apparatus.

Moreover, in each of the above-described embodiments, a case of testing using two types of spreading codes has been described, but the present invention may also be applied to the case of testing using three or more types of spreading codes. Further, in each of the above-described embodiments, a case of using a packet as a unit has been described, but the present invention is by no means limited in this respect, and a plurality of packets such as IIT, frame or sub-frame may also be used as a unit.

The present application is based on Japanese Patent Application No. 2004-172411 filed on Jun. 10, 2004, the entire content of which is expressly incorporated by reference herein.

### INDUSTRIAL APPLICABILITY

The present invention is suitable for use in a testing apparatus for testing reception performance of the communication terminal apparatus used in a wireless communication system.

1-4. (canceled)

5. A testing apparatus that sends packets after spreading to a communication terminal apparatus and tests reception performance of the communication terminal apparatus using error rate of received packets of the communication terminal apparatus, the testing apparatus comprising:
a first spreading code generating section that generates a first spreading code corresponding to a first base station;
a second spreading code generating section that generates a second spreading code corresponding to a second base station;
a transmission packet generating section that generates a packet series to be transmitted to the communication terminal apparatus;
a transmission control section that controls a timing of switching between the first spreading code and the second spreading code;
a selection section that selects one of the first spreading code and the second spreading code based on control of the transmission control section;
a spreading section that multiplies each packet of the packet series generated at the transmission packet generating section by the spreading code selected by the selection section.

6. A testing apparatus that sends packets after spreading to a communication terminal apparatus and tests reception performance of the communication terminal apparatus using error rate of received packets of the communication terminal apparatus, the testing apparatus comprising:
a first spreading code generating section that generates a first spreading code corresponding to a first base station;
a second spreading code generating section that generates a second spreading code corresponding to a second base station;
a transmission packet generating section that generates a first packet series and a second packet series to be transmitted to the communication terminal apparatus; and
a spreading section that multiplies the first packet series by the first spreading code and multiplies the second packet series by the second spreading code.

7. A testing method that sends packets after spreading to a communication terminal apparatus and tests reception performance of the communication terminal apparatus using error rate of received packets of the communication terminal apparatus, the testing method comprising:
a first spreading code generating step of generating a first spreading code corresponding to a first base station;
a second spreading code generating step of generating a second spreading code corresponding to a second base station;
a transmission packet generating step of generating a packet series for the communication terminal apparatus;
a transmission control step of controlling a timing of switching between the first spreading code and the second spreading code;
a selection step of selecting one of the first spreading code and the second spreading code based on control of the transmission control step; and
a spreading step of multiplying each packet of the packet series generated at the transmission packet generating step by the spreading code selected by the selection step.

8. A testing method that sends packets after spreading to a communication terminal apparatus and tests reception performance of the communication terminal apparatus using error rate of received packets of the communication terminal apparatus, the testing method comprising:
a first spreading code generating step of generating a first spreading code corresponding to a first base station;
a second spreading code generating step of generating a second spreading code corresponding to a second base station;
a transmission packet generating step of generating a first packet series and a second packet series to be transmitted to the communication terminal apparatus; and
a spreading step of multiplying the first packet series by the first spreading code and multiplies the second packet series by the second spreading code.
